(19) United States
(12) Patent Application Publication
(10) Pub. No.: US 2026/0029427 A1
(43) Pub. Date: Jan. 29, 2026

(54) MANUFACTURING JIG FOR ELECTRICAL CONNECTION DEVICE AND METHOD OF MANUFACTURING ELECTRICAL CONNECTION DEVICE

(71) Applicant: Kabushiki Kaisha Nihon Micronics, Tokyo (JP)

(72) Inventors: Toshinaga TAKEYA, Aomori (JP); Takahiro FUKUSHI, Aomori (JP); Hideki HIROTA, Aomori (JP)

(21) Appl. No.: 19/350,747

(22) Filed: Oct. 6, 2025

Related U.S. Application Data
(63) Continuation of application No. PCT/JP2024/005804, filed on Feb. 19, 2024.

(30) Foreign Application Priority Data
Apr. 19, 2023 (JP) 2023-068480

(51) Int. Cl. G01R 1/067; G01R 1/04; H01R 33/76

(52) U.S. Cl. CPC G01R 1/06705; G01R 1/0416; H01R 33/7664

(57) ABSTRACT

A manufacturing jig for an electrical connection device includes a jig including a first guide plate and a second guide plate each including a through hole penetrating from a first surface to a second surface, the first guide plate and the second guide plate laminated to be movable relative to each other along the first surface. The through hole includes a common portion extending in a first direction in a plan view, a first guide part extending from the common portion in a second direction different from the first direction, and a second guide part extending from the common portion in a third direction different from the first and second directions. The jig is configured so that probes can be inserted into each of the first guide part and the second guide part, through the first guide plate and the second guide plate successively.

### CROSS-REFERENCE TO RELATED APPLICATIONS

The present application is a continuation of International Application No. PCT/JP2024/005804, filed on February 19, 2024, and based upon and claims the benefit of priority from Japanese Patent Application No. 2023-068480, filed on April 19, 2023, the entire contents of which are incorporated herein by reference.

### TECHNICAL FIELD

The present application relates to a manufacturing jig for an electrical connection device used for inspection of an object to be inspected, and a method of manufacturing an electrical connection device.

### BACKGROUND ART

An electrical connection device having a probe is used for inspection of an object to be inspected, such as an integrated circuit, and the probe is brought into contact with the object to be inspected. During inspection using the electrical connection device, one end of the probe is brought into contact with an electrode terminal of the object to be inspected. The other end of the probe is electrically connected to a wiring pattern arranged on a circuit board of the electrical connection device. The wiring pattern is electrically connected to an inspection device such as a multimeter. Electrical signals can be transmitted and received between the object to be inspected and the inspection device through the probe.

### SUMMARY

When an electrical connection device is manufactured, it is necessary to join a probe to a circuit board so that an end of the probe to be brought into contact with an electrode terminal of an object to be inspected (hereinafter referred to as “contact portion”) is arranged at a proper position with high precision. Furthermore, it is necessary to join probes to the circuit board at a narrow pitch in the electrical connection device due to a narrower pitch of the electrode terminal of the object to be inspected.

It is an object of the present application to provide a manufacturing jig for an electrical connection device and a method of manufacturing an electrical connection device, which can join a probe to a circuit board with high precision and a narrow pitch.

A manufacturing jig for an electrical connection device according to an aspect of the present application includes a jig including a first guide plate and a second guide plate each including a through hole penetrating from a first surface to a second surface, and laminated to be movable relative to each other along the first surface. The through hole includes a common portion extending in a first direction in a plan view, a first guide part extending from the common portion in a second direction, different from the first direction, and a second guide part extending from the common portion in a third direction, different from the first and second directions. The jig is configured so that probes can be inserted into the first guide part and the second guide part, through the first guide plate and the second guide plate successively.

According to the present application, it is possible to provide a manufacturing jig for an electrical connection device and a method of manufacturing an electrical connection device, which can join a probe to a circuit board with high precision and a narrow pitch.

### BRIEF DESCRIPTION OF THE DRAWINGS

FIG. 1 is a schematic view illustrating a configuration of a manufacturing jig according to an embodiment.

FIG. 2 is a schematic cross-sectional view along a direction II-II in FIG. 1, illustrating a configuration of the manufacturing jig according to the embodiment.

FIG. 3 is a schematic plan view illustrating a configuration of the manufacturing jig according to the embodiment.

FIG. 4 is a schematic plan view illustrating a shape of a through hole formed in a guide plate of the manufacturing jig according to the embodiment.

FIG. 5 is a schematic plan view illustrating a shape of a through hole formed in a guide plate of a comparative example.

FIG. 6A is a schematic front view for explaining a method of storing a probe in the manufacturing jig according to the embodiment (Part 1).

FIG. 6B is a schematic cross-sectional view for explaining the method of storing the probe in the manufacturing jig according to the embodiment (Part 1).

FIG. 6C is a schematic plan view illustrating the method of storing the probe in the manufacturing jig (Part 1).

FIG. 7A is a schematic front view illustrating a method of storing a probe in the manufacturing jig (Part 2).

FIG. 7B is a schematic cross-sectional view illustrating the method of storing the probe in the manufacturing jig (Part 2).

FIG. 7C is a schematic plan view illustrating the method of storing the probe in the manufacturing jig (Part 2).

FIG. 8A is a schematic plan view illustrating a position of a probe in a through hole of a first guide plate.

FIG. 8B is a schematic plan view illustrating a position of a probe in the through hole of a second guide plate.

FIG. 9A is a schematic cross-sectional view illustrating a state of a probe inserted in the jig.

FIG. 9B is a schematic cross-sectional view illustrating another state of a probe inserted in the jig.

FIG. 9C is a schematic cross-sectional view illustrating another state of a probe inserted in the jig.

FIG. 9D is a schematic cross-sectional view illustrating another state of a probe inserted in the jig.

FIG. 9E is a schematic cross-sectional view illustrating another state of a probe inserted into the jig.

FIG. 10 is a schematic view for explaining a method of correcting orientation of a probe in in the jig.

FIG. 11 is a flowchart for explaining a method of joining a probe to a circuit board using the manufacturing jig according to the embodiment.

FIG. 12 is a schematic view for explaining a method of joining a probe to a circuit board using the manufacturing jig according to the embodiment (Part 1).

FIG. 13 is a schematic view for explaining the method of joining a probe to a circuit board using the manufacturing jig according to the embodiment (Part 2).

FIG. 14A is a schematic plan view illustrating a shape of a through hole formed in a guide plate of a manufacturing jig according to another embodiment (Part 1).

FIG. 14B is a schematic plan view illustrating another shape of a through hole formed in a guide plate of a manufacturing jig according to another embodiment (Part 2).

FIG. 14C is a schematic plan view illustrating another shape of a through hole formed in a guide plate of a manufacturing jig according to another embodiment (Part 3).

### DESCRIPTION OF EMBODIMENTS

Next, some embodiments of the present application will be described with reference to the drawings. In the description of the following drawings, the same or similar parts are denoted by the same or similar reference signs. However, it should be noted that the drawings are schematic, and the thickness ratio of parts is different from the actual one. Moreover, there are parts in which dimensional relationships and proportions differ among the drawings. The following embodiments exemplify a device and a method realizing technical concepts of the present application, and the embodiments of the present application do not specify the material, shape, structure, arrangement, or the like, of components as described below.

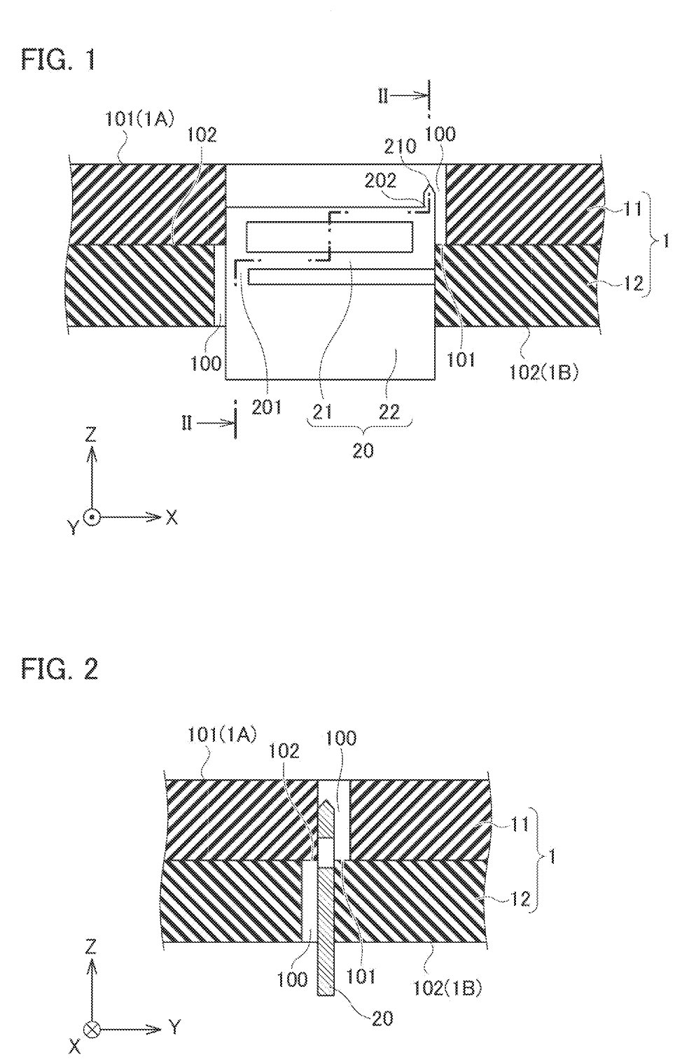

FIGS. 1 to 3 illustrate a manufacturing jig for an electrical connection device according to an embodiment of the present application. The manufacturing jig is used for manufacturing an electrical connection device. A probe 20 is joined to a circuit board of the electrical connection device and comes into contact with an object to be inspected. As illustrated in FIG. 1, the probe 20 includes an arm 21 having a cantilever structure, and a support portion 22 connected to a fixation end 201 of the arm 21. A contact portion 210 is a tip of a free end 202 of the arm 21, and contacts the object to be inspected.

The manufacturing jig according to the embodiment includes a jig 1 including a first guide plate 11 and a second guide plate 12. A through hole 100 is formed in each of the first guide plate 11 and the second guide plate 12, penetrating from a first surface 101 to a second surface 102 facing in a direction opposite to the first surface 101. The probe 20 held by the jig 1 is joined to a circuit board of the electrical connection device, as will be described in detail below. The circuit board of the electrical connection device is, for example, an interposer board. For inspecting the object to be inspected, the object to be inspected and an inspection device, such as a multimeter, are electrically connected through the probe 20 with the contact part 210 in contact with the electrode terminal of the object to be inspected, and signal wirings formed on the circuit board.

The first guide plate 11 and the second guide plate 12 of the jig 1 are configured to be laminated so that the probe 20 penetrates through the through holes 100 of the first guide plate 11 and the second guide plate 12 successively. The first guide plate 11 and the second guide plate 12 are laminated so that the second surface 102 of the first guide plate 11 and the first surface 101 of the second guide plate 12 face each other. Hereinafter, the first surface 101 of the first guide plate 11 is also referred to as “first main surface 1A” of the jig 1, and the second surface 102 of the second guide plate 12 is referred to as “second main surface 1B” of the jig 1.

Hereinafter, the first guide plate 11 and the second guide plate 12 are referred to as “guide plate 10” when an explanation is not limited to one or the other. Each of the guide plates 10 has a through hole 100 through which the probe 20 penetrates.

As illustrated in FIG. 1, a penetration direction of the through hole 100, that is, a thickness direction of the guide plate 10, is aligned with a Z direction. In FIG. 1, the Z direction is a vertical direction of the paper surface, an X direction is a lateral direction of the paper surface, and a Y direction is a depth direction of the paper surface. In the description of the embodiment, a view in the Y direction is referred to as a front view. The front view illustrates a cross section of the guide plate 10 along a plane parallel to the Z direction.

The jig 1 holds the probe 20 in a state where the probe 20 penetrates through the through hole 100 of the first guide plate 11 and the second guide plate 12. When viewed in the X and Y directions, a part of the support portion 22 of the probe 20 is exposed from the second main surface 1B of the jig 1.

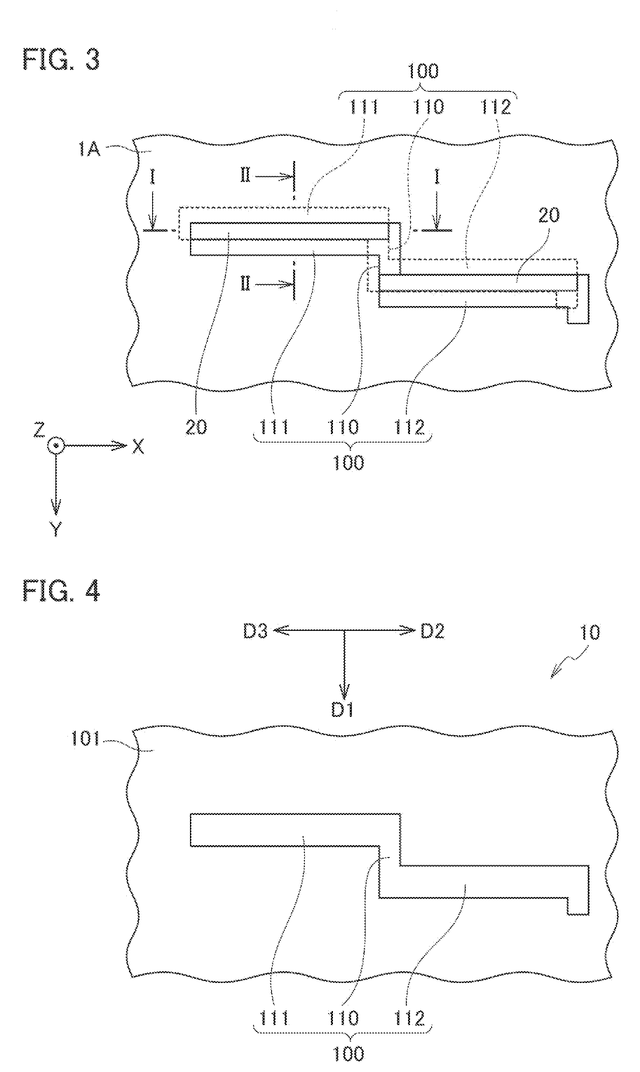

FIG. 2 is a cross-sectional view of the jig 1 along a direction II-II in FIG. 1. FIG. 3 is a plan view of the jig 1 in the Z direction. FIG. 1 is a cross-sectional view in a direction I-I in FIG. 3, and FIG. 2 is a cross-sectional view in the direction II-II in FIG. 3. The through hole 100 in the second guide plate 12 is illustrated by a dashed line through the first guide plate 11 in FIG. 3. The probe 20 is rectangular in a plan view from a surface normal direction to the first surface 101.

As illustrated in FIG. 3, the through hole 100 includes a common portion 110, a first guide part 111, and a second guide part 112. The common portion 110, the first guide part 111, and the second guide part 112 extend linearly in a plan view. The direction in which the common portion 110 extends is hereinafter referred to as “first direction”. The first guide part 111 extends from the common portion 110 in a direction different from the first direction in a plan view. Hereinafter, the direction in which the first guide part 111 extends is referred to as “second direction”. The second guide part 112 extends from the common portion in a direction different from the first direction and the second direction in a plan view. Hereinafter, the direction in which the second guide part 112 extends is referred to as “third direction”. The first guide part 111 may be connected to one end (hereinafter, also referred to as “first end”) of the common portion 110. The second guide part 112 may be connected to the other end (hereinafter, also referred to as “second end”) of the common portion 110.

The jig 1 holds probes 20 inserted into the first guide part 111 and the second guide part 112. The jig 1 is configured so that the first guide plate 11 and the second guide plate 12 are movable relative to each other along the first surface 101 with first probe 20 inserted into the first guide part 111 and second probe 20 inserted into the second guide part 112. As will be described in detail below, the first guide plate 11 and the second guide plate 12 are moved relative to each other in a direction crossing the penetration direction of the through hole 100 so that the probes 20 are interposed between the first guide plate 11 and the second guide plate 12. Hereinafter, a region including the first guide part 111 and the second guide part 112, through which the probes 20 penetrate, is also referred to as a guide part. The jig 1 is configured so that the probes 20 can be inserted into each of the first guide part 111 and the second guide part 112, through the first guide plate 11 and the second guide plate 12 successively.

FIG. 4 illustrates an example of a shape of the through hole 100 of the guide plate 10. The common portion 110 extends in a first direction D1 viewed in a plan view. The first guide part 111 extends in a second direction D2 orthogonal to the first direction D1 in a plan view, and the second guide part 112 extends in a third direction D3 opposite to the second direction D2 in a plan view. That is, in the guide plate 10 illustrated in FIG. 4, the second direction D2 and the third direction D3 are orthogonal to the first direction D1 in a plan view, and the second direction D2 and the third direction D3 are opposite directions. The first direction D1 may be parallel to the Y direction, and the second direction D2 and the third direction D3 may be parallel to the X direction.

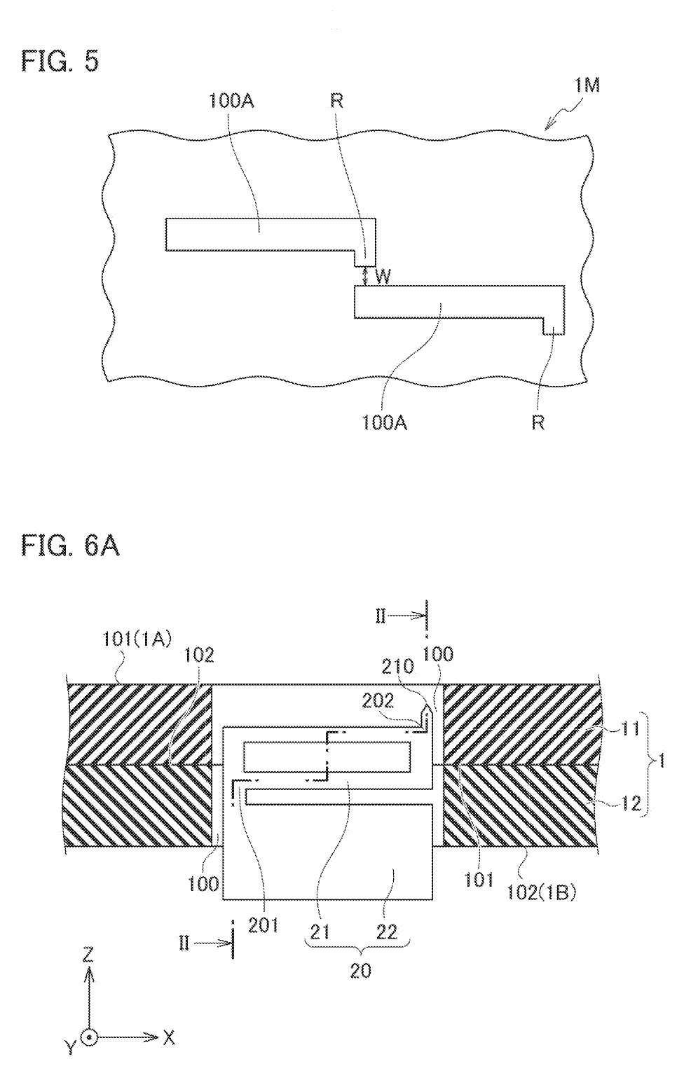

When a rectangular through hole is formed in a flat plate in a plan view, it is difficult to form all four corners of the through hole at right angles, and it is common to form a relief portion at one corner of the through hole by performing relief processing. Therefore, a relief portion R is formed in a guide hole 100A, through which the probe 20 penetrates, in a comparison jig 1M according to a comparative example as illustrated in FIG. 5. However, when the relief portion R is formed in the guide hole 100A, a predetermined distance W is required between adjacent guide holes 100A, as illustrated in FIG. 5. This hinders a narrower arrangement pitch of the probes 20.

The common portion 110 of the through hole 100 in the guide plate 10 as illustrated in FIG. 4 is formed as a relief portion of the first guide part 111. Thus, the arrangement pitch of the probes 20 can be made narrowed by connecting the relief portion of the first guide part 111 with the second guide part 112.

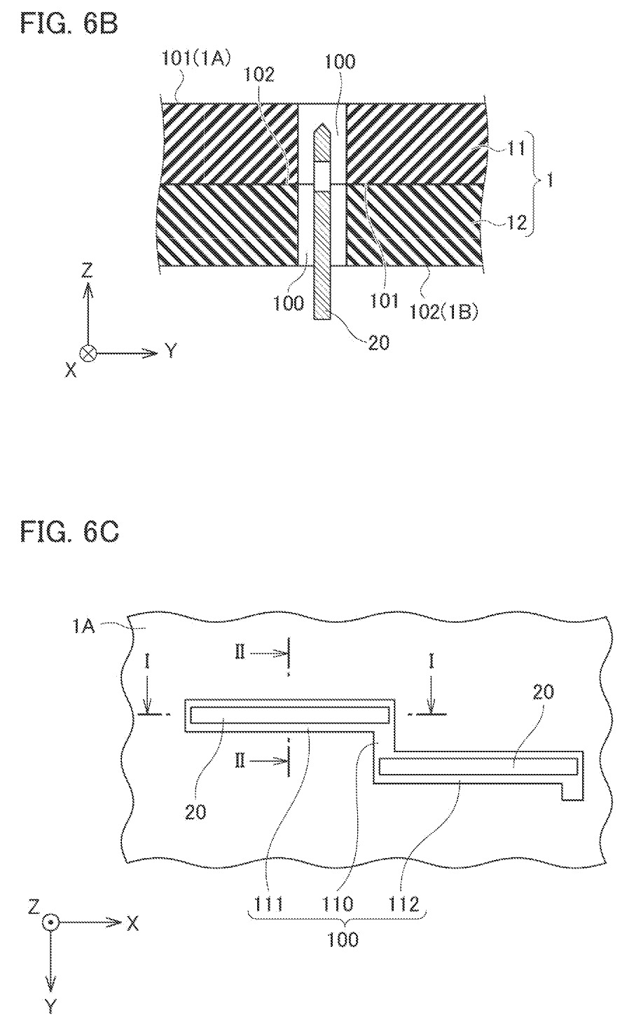

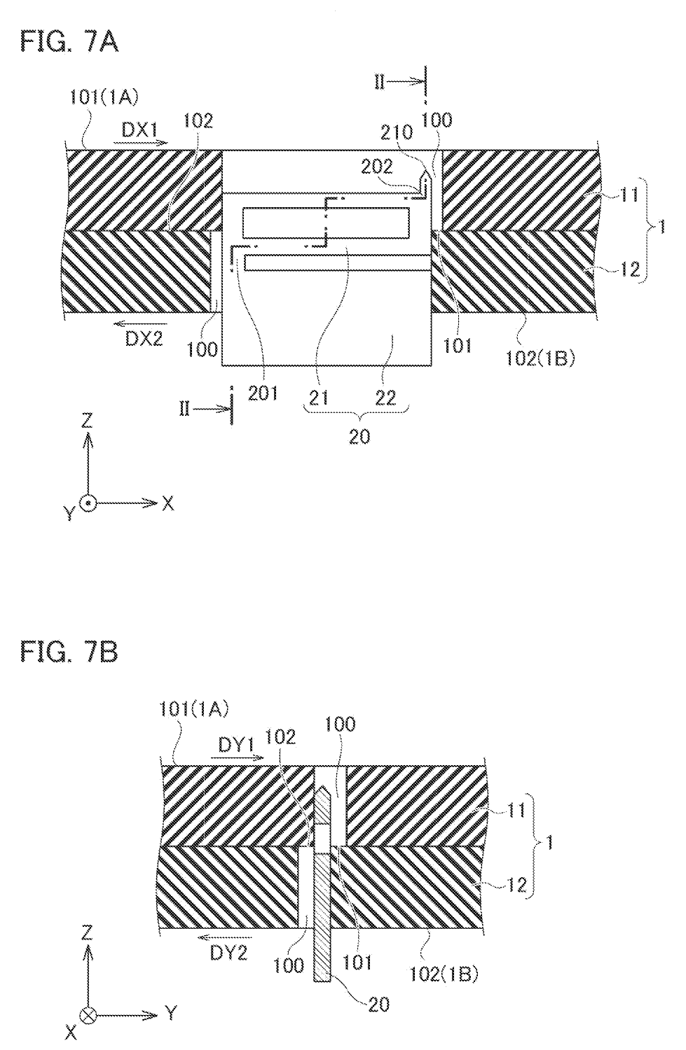

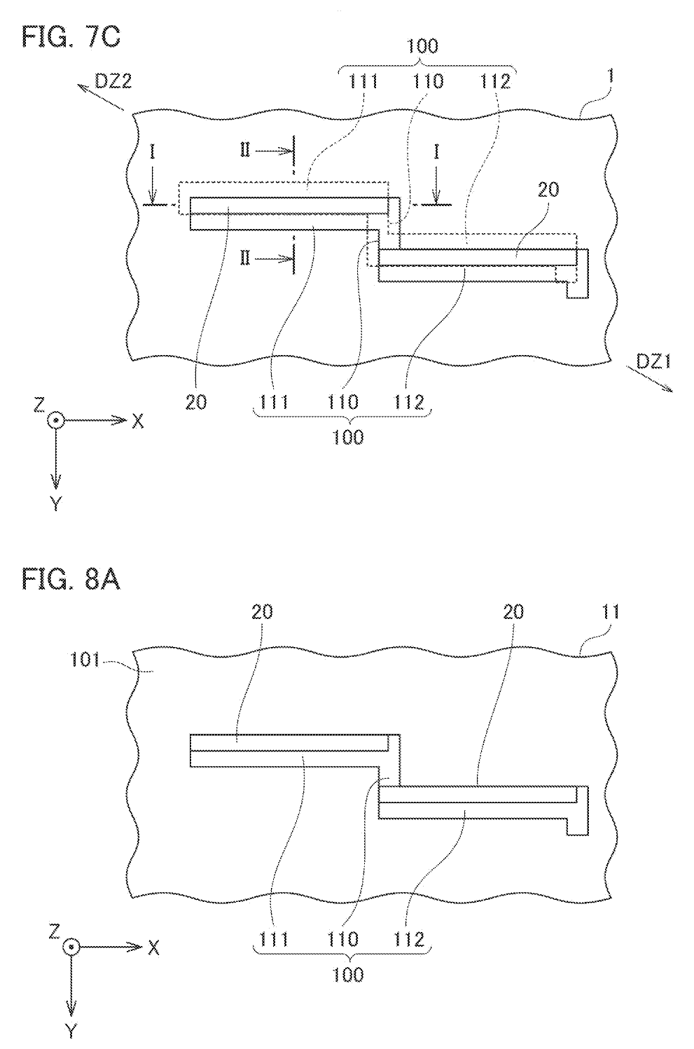

With reference to FIGS. 6A, 6B, 6C, 7A, 7B, and 7C, an example of a method of storing the probes 20 in the jig 1 will be described below. FIGS. 6A and 7A are front views. FIGS. 6B and 7B are cross-sectional views along the direction II-II of FIGS. 6A and 7A. FIGS. 6C and 7C are plan views in the Z direction.

First, a manufacturing jig including the jig 1, and the probes 20 are prepared. Then, the position of the through hole 100 of the first guide plate 11, and the position of the through hole 100 of the second guide plate 12, are adjusted to correspond to each other so that the probes 20 penetrate the through holes 100 of the first guide plate 11 and the second guide plate 12 successively. At this point, the positions of inner wall surfaces of the through holes 100 of the first guide plate 11 and the second guide plate 12 correspond to each other. Then, as illustrated in FIGS. 6A, 6B, and 6C, the probes 20 are inserted into the through holes 100 of the first guide plate 11 and the second guide plate 12. In other words, the first probe 20 is inserted into the first guide part 111 and the second probe 20 is inserted into the second guide part 112. At this point, the probes 20 are inserted into the through holes 100 of the first guide part 111 and the second guide part 112 so that a part of the support portion 22 is exposed below the second main surface 1B of the jig 1.

Next, with the probes 20 inserted into each of the first guide part 111 and the second guide part 112, the first guide plate 11 and the second guide plate 12 are moved relative to each other in a direction intersecting the penetration direction (Z direction) of the through holes 100. That is, as illustrated in FIGS. 7A, 7B, and 7C, the first guide plate 11 and the second guide plate 12 are moved relative to each other along the first surface 101. For example, as illustrated in FIG. 7A, as for the X direction, the first guide plate 11 is moved in the right direction on the paper surface, as indicated by an arrow DX1, and the second guide plate 12 is moved in the left direction on the paper surface, as indicated by an arrow DX2. Then, as for the Y direction, the first guide plate 11 is moved in the right direction on the paper surface, as indicated by an arrow DY1, and the second guide plate 12 is moved in the left direction on the paper surface, as indicated by an arrow DY2. That is, as illustrated in FIG. 7C, in the XY plane, the first guide plate 11 is moved in the right lower direction on the paper surface, as indicated by an arrow DZ1, and the second guide plate 12 is moved in the upper left direction on the paper surface, as indicated by an arrow DZ2.

Hereinafter, moving the first guide plate 11 and the second guide plate 12 relative to each other is also referred to as “sliding the guide plates”. When sliding the guide plates, the first guide plate 11 and the second guide plate 12 are moved relative to each other in a direction crossing the penetration direction of the through holes 100. For example, the first guide plate 11 and the second guide plate 12 are moved relative to each other along the first surface 101. A position of either of the first guide plate 11 and the second guide plate 12 may be fixed, and a position of the other of the first guide plate 11 and the second guide plate 12 may be moved. The guide plate 10 may be moved in either the X direction or the Y direction.

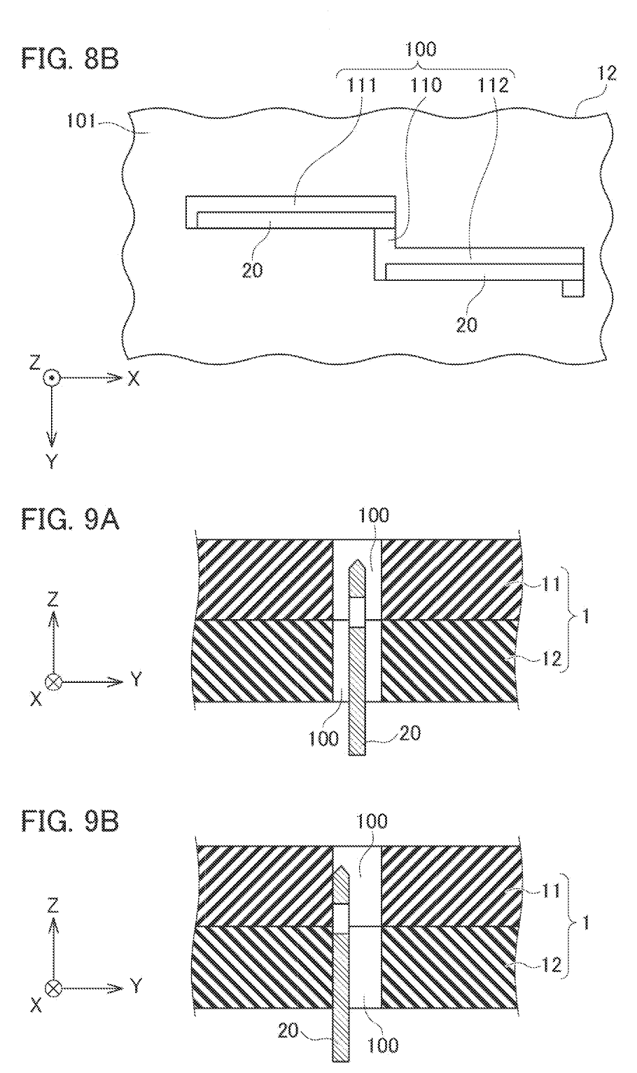

By the sliding the guide plates, in each of the first guide part 111 and the second guide part 112 of the guide plate 10, the probes 20 are brought into contact with one of two opposite inner wall surfaces of the through hole 100, and separated from the other one of the two opposite inner wall surfaces of the through hole 100. For example, as illustrated in FIGS. 8A and 8B, two adjacent side surfaces of the probes 20 abut against an inner wall surface of the through hole 100 of the first guide plate 11, and the other two adjacent side surfaces of the probes 20 abut against an inner wall surface of the through hole 100 of the second guide plate 12. At this point, the probes 20 is separated from the inner wall surface of the through hole 100 of the second guide plate 12 in the same orientation as the inner wall surface abutting against the probes 20 of the through hole 100 of the first guide plate 11. The probes 20 abuts against the inner wall surface of the through hole 100 of the second guide plate 12 in the same orientation as the inner wall surface of the through hole 100 of the first guide plate 11 that is separated from the probes 20.

The probes 20 are interposed between the first guide plate 11 and the second guide plate 12 in each of the first guide part 111 and the second guide part 112 by moving the first guide plate 11 and the second guide plate 12 relative to each other in the XY plane, as described above. The jig 1 clamps the probes 20 by the guide plate 10 to fix the position of the probes 20.

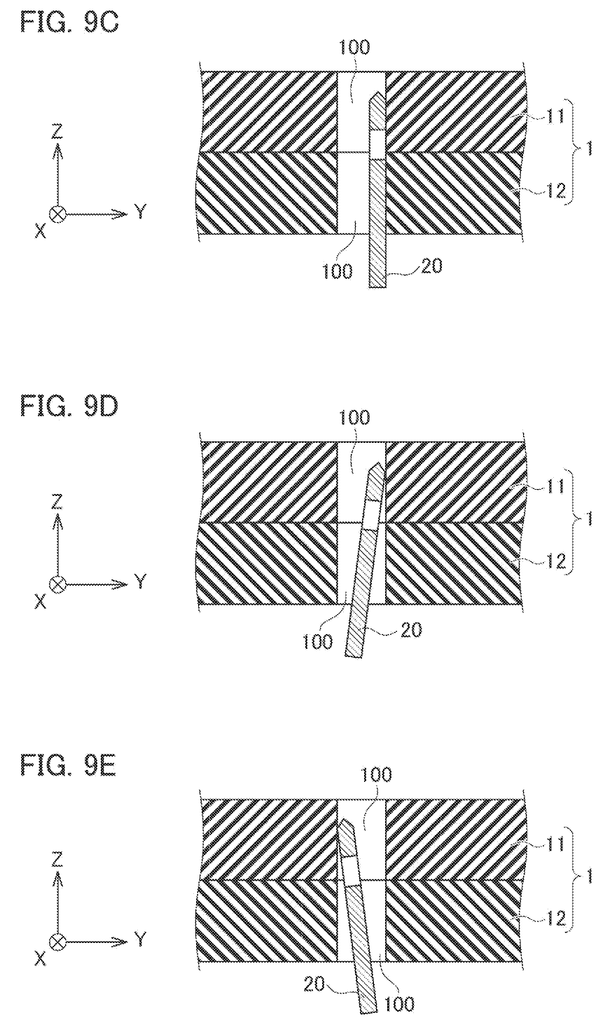

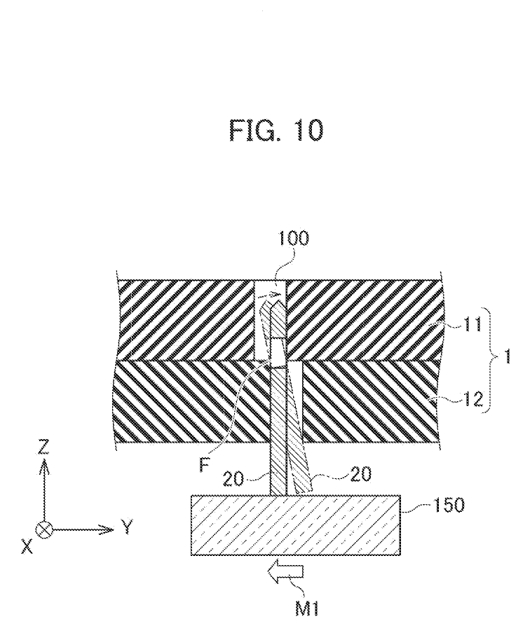

FIGS. 9A to 9E illustrate a general orientation of the probe 20 inserted into the through hole 100 of the jig 1 before sliding the guide plates. FIG. 9A illustrates a state of the probe 20 held in the center of the through hole 100. FIGS. 9B and 9C illustrate a state of the probe 20 located to one side surface of the through hole 100. FIGS. 9D and 9E illustrate a state of the probe 20 tilted inside the through hole 100.

When the electrical connection device is manufactured by joining the probe 20 to the circuit board using the jig 1, it is necessary that the probe 20 is held in the jig 1 in a correct orientation. “Correct orientation” means that the probe 20 is inserted straight into the through hole 100 to a predetermined position. Regardless of the states of the probe 20 illustrated in FIGS. 9A to 9E, the probe 20 is pressed against the inner wall surface of the through hole 100 by sliding the guide plate, and held in the jig 1 after being corrected to be in the correct orientation. Hereinafter, it is assumed that the probe 20 is held in the jig 1 in the correct orientation and that the probe 20 is held normally in the jig 1.

However, the probe 20 might not be held normally in the jig 1 after the guide plate slides. In this case, it is necessary to correct the orientation of the probe 20. The orientation of the probe 20 is corrected in the following manner, for example.

For example, when the probe 20 is inclined inside the through hole 100, as illustrated in FIG. 10, a jig substrate 150 is moved in parallel with the jig 1, as illustrated by an arrow M1 while pressing the probe 20 into the through hole 100 by the jig substrate 150 brought into contact with the tip of the probe 20. At this point, the probe 20 is rotated, as illustrated by a dashed arrow, with a contact F between an end of an opening of the through hole 100 of the second guide plate 12 and the probe 20 as a fulcrum. The probe 20 can be corrected to be in the correct orientation by moving the jig substrate 150 and sliding the guide plate repeatedly.

According to the method of storing a probe described above, the arrangement pitch of the probes 20 can be narrowed, so that the probes 20 can be stored in the jig 1 in the correct orientation.

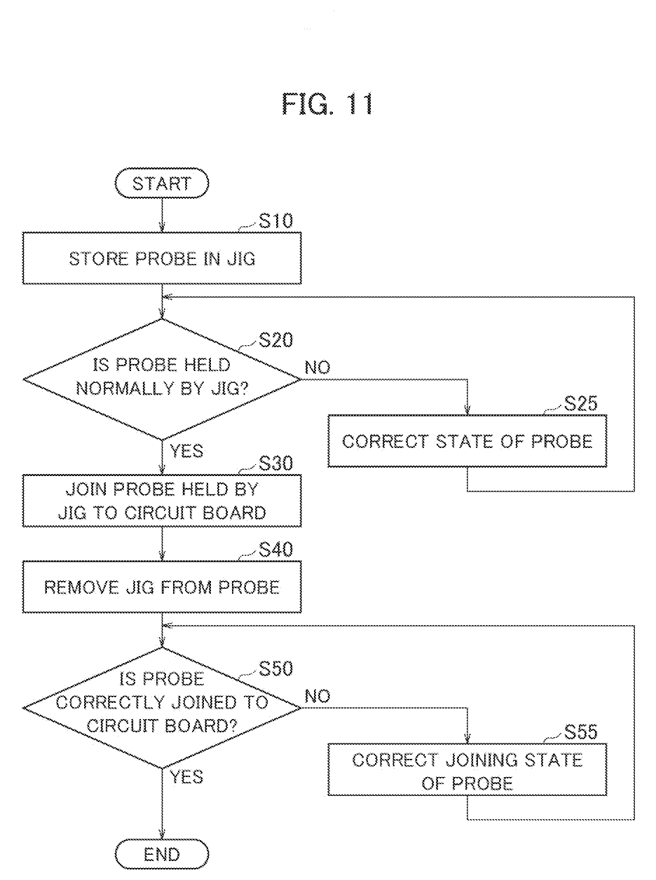

With reference to a flowchart in FIG. 11, an example of a method of manufacturing an electrical connection device by joining the probe 20 to a circuit board using a manufacturing jig including the jig 1 will be described below.

In step S10 of FIG. 11, the probe 20 is stored in the jig 1, as described with reference to FIGS. 6A, 6B, 6C, 7A, 7B, and 7C.

In step S20, the state of the probe 20 held by the jig 1 is inspected. In step S20, whether or not the probe 20 is held normally by the jig 1 is also inspected. If the probe 20 is held normally by the jig 1, the process proceeds to step S30. However, if the probe 20 is not held normally by the jig 1, the process proceeds to step S25.

In step S25, the state of the probe 20 is corrected so that the probe 20 is held normally by the jig 1. For example, if the probe 20 is not held normally by the jig 1, the orientation of the probe 20 is corrected in a manner described with reference to FIG. 10. Thereafter, the process returns to step S20.

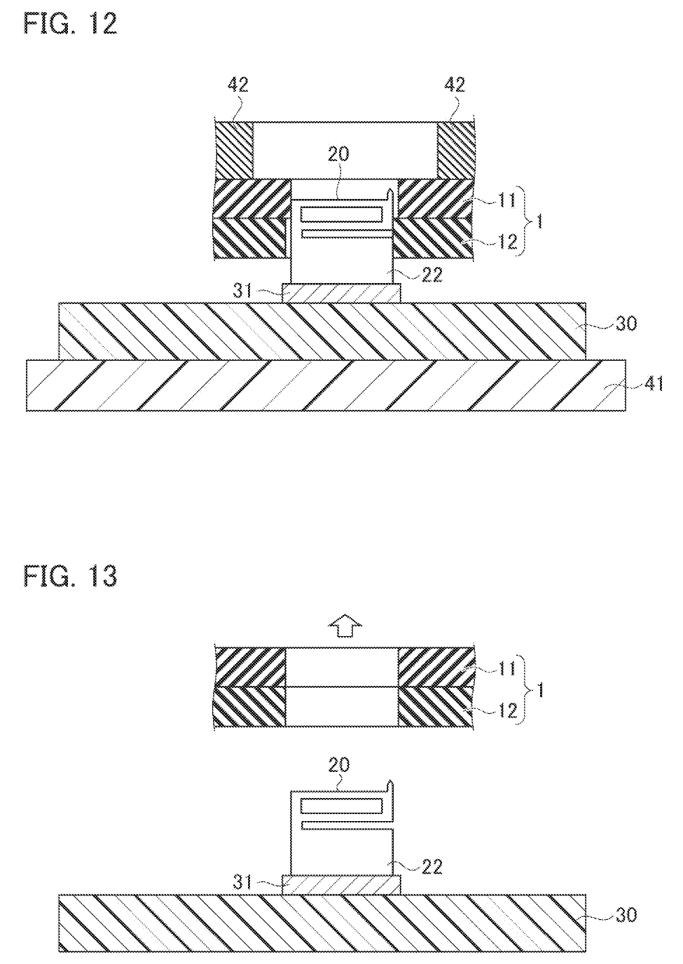

In step 30, the probe 20 held by the jig 1 is joined to the circuit board 30. For example, as illustrated in FIG. 12, a conductive joining material 31 such as solder is applied to a predetermined joining region of the circuit board 30, and the support portion 22 of the probe 20 is joined to the circuit board 30 by the joining material 31. The probe 20 is electrically connected to a wiring pattern (not illustrated) of the circuit board 30. When solder is used for the joining material 31, residual stress inside the solder may be eliminated by slowly cooled aging after reflow soldering for joining the probe 20 and the circuit board 30. As illustrated in FIG. 12, the circuit board 30 may be mounted on a base plate 41 in the shape of a plate, and the jig 1 and the circuit board 30 may be interposed between a guide presser 42, in the shape of a ring, and the base plate 41 to reinforce the mechanical strength of the jig 1. Thus, the flatness of the jig 1 can be stabilized.

After the probe 20 is joined to the circuit board 30, the jig 1 is removed from the probe 20 in step S40 of FIG. 11, as illustrated in FIG. 13. For example, after a space is provided between the through hole 100 and the probe 20 by sliding the guide plates, the jig 1 is isolated from the circuit board 30.

Then, in step S50 of FIG. 11, whether or not the probe 20 is correctly joined to the circuit board 30 is inspected. For example, whether or not the probe 20 is joined straight to a predetermined joining area of the circuit board 30 is inspected by camera photography or the like. If there is a defect in the probe 20 joined to the circuit board 30, the process proceeds to step S55 to correct the joining state of the probe 20. Then, the process returns to step S50.

If the probe 20 is joined to the circuit board 30 without any problem in step S50, the process ends. Thus, the process of joining the probe 20 to the circuit board 30 by the manufacturing jig including the jig 1 is completed.

As described above, in the manufacturing jig of an electrical connection device according to the embodiment, an entire side surface of the probe 20 contacts the inner wall surface of the through hole 100. Therefore, the probe 20 can be stably held by the jig 1. A plurality of guide parts, into which the probes 20 are inserted, are connected through the common portion 110, which also serves as a relief portion, so that a distance between the probes 20 can be narrowed. Therefore, with the manufacturing jig according to the embodiment, the probes 20 can be joined to the circuit board 30 with high precision and a narrow pitch.

When the probes 20 are joined to the circuit board 30 using the jig 1, the probes 20 after manufacturing may be directly aligned with the jig 1 without using a tray for storing the probes 20. Thus, a step of storing the probes 20 in a tray is omitted, and a step of joining the probes 20 to the circuit board 30 can be shortened.

Other Embodiments

Although the present invention has been described by embodiments as in the description above, it should not be understood that the statements and drawings which form part of this disclosure are intended to limit the invention. Various alternative embodiments, examples and techniques of operation will be apparent to those skilled in the art from this disclosure.

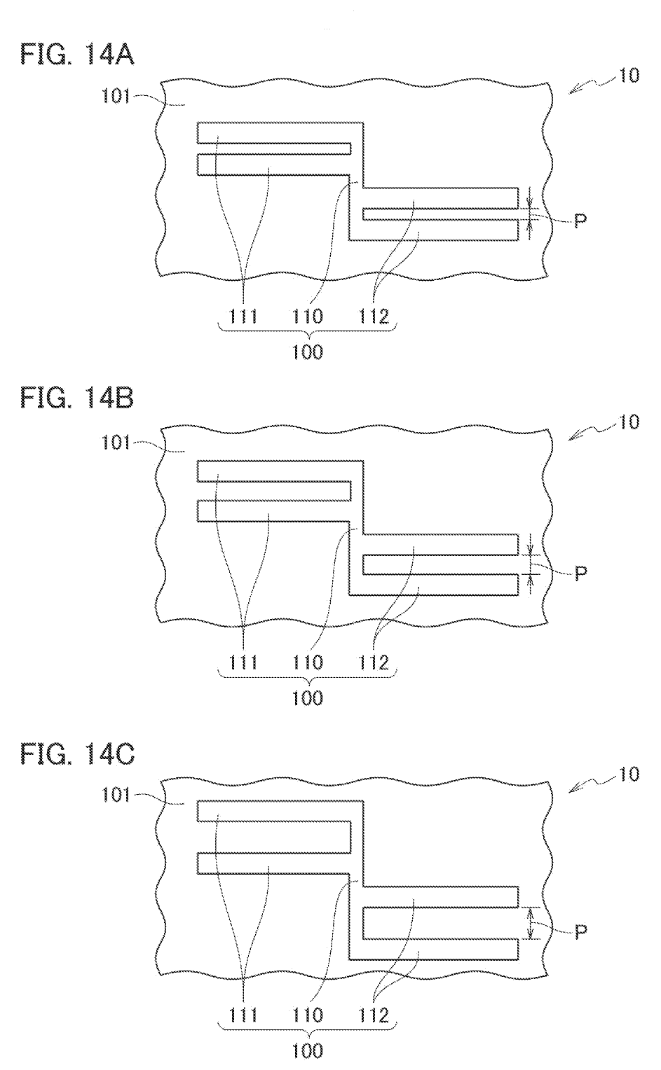

For example, one through hole 100 including two guide parts connected by the common portion 110 is described above as an example. However, one through hole 100 may include a plurality of guide parts connected to the common portion 110 and extending parallel to the first guide part 111, and another plurality of guide parts connected to the common portion 110 and extending parallel to the second guide part 112. The arrangement pitch of the probes 20 can be further narrowed by increasing the number of guide parts connected to the common portion 110. For example, the through hole 100 illustrated in FIGS. 14A to 14C includes two first guide parts 111 and two second guide parts 112. FIGS. 14A to 14C differ in an interval P between the guide parts. An interval between the probes 20 held by the jig 1 is set according to the pitch of the electrode terminals of the object to be inspected. Therefore, the shape of the through hole 100 of the jig 1 is determined according to arrangement of electrode terminals of the object to be inspected.

One through hole 100 formed in the guide plate 10 is illustrated above, but it is of course possible to form a plurality of through-holes 100 in the guide plate 10. In addition, a case where extension directions of the first guide part 111 and the second guide part 112 are parallel is illustrated, but the extension directions of the first guide part 111 and the second guide part 112 may intersect.

As described above, the present invention naturally includes various embodiments which are not described herein. Therefore, the technical scope of the present invention is defined only by matters specifying the invention according to the claims that are reasonable from the description above.

What is claimed is:

1. A manufacturing jig for manufacturing an electrical connection device including probes that comes into contact with an object to be inspected, comprising:
a jig comprising a first guide plate and a second guide plate each including a through hole penetrating from a first surface to a second surface facing in a direction opposite to the first surface, the first guide plate and the second guide plate laminated to be movable relative to each other along the first surface, wherein
the through hole includes:
a common portion extending in a first direction in a plan view from a surface normal direction to the first surface;
a first guide part extending from the common portion in a second direction, different from the first direction in the plan view; and
a second guide part extending from the common portion in a third direction, different from the first and second directions in the plan view, and wherein
the jig is configured so that the probes can be inserted into each of the first guide part and the second guide part, through the first guide plate and the second guide plate successively.

2. The manufacturing jig according to claim 1, wherein
the first guide part extends in the second direction, orthogonal to the first direction, from a first end of the common portion in the plan view, and
the second guide part extends in the third direction opposite to the second direction, from a second end of the common portion in the plan view.

3. The manufacturing jig according to claim 1, wherein two adjacent side surfaces of the probes abut against an inner wall surface of the through hole of the first guide plate, and other two adjacent side surfaces of the probes abut against an inner wall surface of the through hole of the second guide plate.

4. The manufacturing jig for an electrical connection device according to claim 1, wherein the through hole includes: a guide part connected to the common portion and extending parallel to the first guide part, and another guide part connected to the common portion and extending parallel to the second guide part.

5. A method of manufacturing an electrical connection device used for inspecting an object to be inspected, comprising:
preparing probes including an arm part having a cantilever structure, and a support portion connected to a fixation end of the arm part;
preparing a jig comprising a first guide plate and a second guide plate each including a through hole penetrating from a first surface to a second surface facing in a direction opposite to the first surface, the first guide plate and the second guide plate laminated to be movable relative to each other along the first surface, the through hole including: a common portion extending in a first direction in a plan view from a surface normal direction to the first surface; a first guide part extending from the common portion in a second direction, different from the first direction in the plan view; and a second guide part extending from the common portion in a third direction, different from the first and second directions in the plan view;
inserting the probes into each of the first guide part and the second guide part to penetrate through the first guide plate and the second guide plate successively, with the first guide plate and the second guide plate being laminated;
holding the probes by the first guide plate and the second guide plate by moving the first guide plate and the second guide plate relative to each other along the first surface with the probes inserted into the first guide plate and the second guide plate; and
joining the probe held by the jig to a circuit board.

6. The method of manufacturing an electrical connection device according to claim 5, wherein the probes are inserted into the through holes of the first guide plate and the second guide plate so that a part of the support portion of each probe is exposed when viewed from the second surface.

7. The method of manufacturing an electrical connection device according to claim 5, wherein the first guide plate and the second guide plate are moved relative to each other along the first surface so that two adjacent side surfaces of the probes abut against an inner wall surface of the through hole of the first guide plate, and two other adjacent side surfaces of the probes abut against an inner wall surface of the through hole of the second guide plate.
